(19) United States
(12) Patent Application Publication
(10) Pub. No.: US 2024/0236609 A1
(43) Pub. Date: Jul. 11, 2024

(54) METHOD OF USING IIR FILTERS FOR THE PURPOSE OF ALLOWING ONE AUDIO SOUND TO ADOPT THE SAME SPECTRAL CHARACTERISTIC OF ANOTHER AUDIO SOUND

(71) Applicant: AUDIO IMPRESSIONS, INC., Oak Park, CA (US)

(72) Inventors: Christopher L. Stone, Oak Park, CA (US); Spencer Stone, West Sacramento, CA (US); Christopher Nicolas Vlavianos, Camarillo, CA (US)

(21) Appl. No.: 18/405,272

(22) Filed: Jan. 5, 2024

Related U.S. Application Data
(60) Provisional application No. 63/437,298, filed on Jan. 5, 2023.

(51) Int. Cl. H04S 7/00; H03H 17/00; H03H 17/02

(52) U.S. Cl. CPC H04S 7/305; H03H 17/0294; H04S 7/307; H03H 2017/009

(57) ABSTRACT

An audio sampler is provided, comprising a sample library having stored therein a plurality of main audio samples and a plurality of infinite impulse response (IIR) coefficients divided into subset, each subset corresponding to one of the main audio samples; a sample playback engine comprising an input receiving the main audio samples and outputting a playback signal; and, an IIR filter receiving the corresponding subset of IIR coefficients and applying the IIR filter to the main audio samples or to the playback signal.

### RELATED APPLICATION

This application claims priority benefit from U.S. Provisional Application Ser. No. 63/437,298, filed on Jan. 5, 2023, the disclosure of which is incorporated herein by reference in its entirety. This Application is also related to U.S. Pat. No. 10,319,353, the disclosure of which is incorporated herein by reference in its entirety.

### BACKGROUND

### 1. Field

The disclosed invention relates to sound processing and, more specifically, to transforming a recorded sound (sample) from one source into the timbral sonic characteristics of another sound source.

### 2. Related Art

A sampler (or audio sampler) is an electronic or digital musical instrument that uses sound recordings (or “samples”) of real instrument sounds (e.g., a piano, violin or trumpet). The samples are pre-recorded and stored in an audio sample library. The samples can be played back by means of the sampler program itself, a MIDI keyboard, sequencer or another triggering device (e.g., electronic drums) to perform or compose music. In conventional sample libraries several recordings are made of the same note at different dynamic (volume) levels. These are known as dynamic layers, such as (FF) meaning very loud, (MF or MP) meaning soft and (PP) meaning very soft. Each dynamic layer of an instrument has its own unique sonic characteristic known as a timbral signature. Timbre, also referred to as tone color or tone quality, is the perceived sound quality of a musical note, sound or tone. Musicians can change the timbre of the music they are playing by using different playing techniques. For example, a violinist can use different bowing styles or play on different parts of the string to obtain different timbres (e.g., playing sul tasto produces a light, airy timbre, whereas playing sul ponticello produces a harsh, even an aggressive tone). For this reason, the greater the number of sampled dynamic layers of an instrument, the more sophisticated and realistic it will sound when performed with a MIDI keyboard or similar music control device connected to a sample playback engine playing the samples.

In digital music production, “footprint” refers to the amount of data storage required for the content of an audio sample library. On a computer or digital note player, especially on modern portable devices, there is often a limited amount of storage space for audio data, or footprint. The standard audio industry solution to reducing the number of audio samples is commonly accomplished via various forms of data compression. Audio data compression is not ideal for a number of reasons. In many compressed audio formats, latency occurs when the compressed audio is decompressed in real-time. This is unacceptable for triggering the audio in a real time performance using a MIDI keyboard or similar device for controlling the performance. Although compressed audio is more suitable for downloading audio over an Internet connection, the compressed format must still be saved locally in a decompressed format on the computer for real-time performance. Footprint conservation, therefore, is not actually accomplished with this method. Compressed audio formats are further limited by the degree of footprint reduction they provide relative to audio quality degradation. Regardless of the audio compression method used, it is not completely lossless in sonic quality once decompressed.

A solution is needed that enable building a sample library that can be used to create realistic sound mimicking real instruments, but which has a reduced footprint. The solution should also enable rapid recreation of the sounds, so that it can be used in live performance and not require heavy computational operations.

In U.S. Pat. No. 10,319,353, the subject inventor has disclosed methods utilizing impulse response (IR) to generate a sample library having small footprint, while still preserving a realistic sound of real musical instruments played at various dynamic levels, with capability to process the audio samples in real time. The disclosed embodiments require small amount of storage space and since the libraries have small footprint, no compression algorithm is required, thus preventing the issue of latency during live performance.

While the solution disclosed in the '353 patent satisfied the objectives noted above, the subject inventor has found that using IRs directly for the sound conversion requires a significant demand on computer processing power. Consequently, when multiple IR processors are required simultaneously (e.g., during live performance), the computer will soon run out of processing power. Thus, a solution is needed that while maintaining the small footprint of the invention disclosed in the '353 patent, also economizes on RAM and CPU requirements.

### SUMMARY

The following summary is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Embodiments disclosed herein solve the storage and processing related issues mentioned in the Background section, while preserving the sound quality of the originally recorded samples. Specifically, disclosed embodiments provide a sample library having small footprint, while requiring very little computer power to recreate the sounds. Consequently, it may be used on portable devices with small storage space and lower processing capability.

Various disclosed embodiments utilize a time-wise short length audio sample called the “target” sample. It is typically a sample of a music instrument, a human voice, or sound effect, but not limited to any particular type of instrument or sound. The target sample is used to generate a setting for a specific type of multi-pole audio filter, called an IIR (Infinite Impulse Response) filter. The IIR filter is then applied to a “destination” audio sound, thereby transforming the destination sound into the timbral sonic characteristics of the target sampled sound. In disclosed embodiments, the target sample can be either a short audio sample of anywhere between 0.0001-1000 milliseconds in time duration, a signal from a synthesizer, or it can be derived from an IR sample disclosed in the '353 patent. The disclosed embodiments also substantially reduce storage requirements. For instance, by eliminating all the samples that can be replace by IIR coefficients via this disclosure, a music sample library consisting of one terabyte of over 100,000 sample, can be condensed to as little as 10 gigabytes with only 1000 samples and corresponding coefficients replacing the rest of the original samples.

The IR's disclosed in the '353 patent and the IIR's disclosed herein are not mutually exclusive. That is, one can use any combination of IR and/or IIR processing on the same library, even simultaneously and in real-time. For instance, embodiments may use an IR for the Harmon mute simulation plus an IIR for the PP (soft dynamics) simulation on the same instrument in real-time. Additionally, if one already has a stored IR library to use in a live performance situation, rather than using the IR processing that may heavily tax the processing power of the system, the IIR processing can be used to play the desired sounds.

As explained in the '353 patent, the IR processing uses a convolution program. Conversely, in disclosed embodiments the IIR processing uses an IIR filter, as will be detailed below. Thus, for library creation one needs to only store the IIR coefficients, and use those coefficients when applying the IIR filter to the destination file during performance, wherein the destination file may be a sample, an IR generated sample, or a synthesizer output signal.

Aspects of this disclosure include a method for constructing an audio sample library stored in a digital form, comprising: obtaining a plurality of main samples, each main sample corresponding to a respective sound, and storing the plurality of main samples in digital form; generating a set of infinite impulse response (IIR) coefficients derived from at least one secondary sample different from any of the main samples, the set of IIR coefficients applicable to IIR filter to modify dynamic level of selected main sample from the plurality of main samples; storing the set of IIR coefficients to thereby form the audio sample library having plurality of main samples and a set of IIR coefficients. In embodiments, the secondary sample(s) has a different dynamic level of any of the plurality of main samples.

Disclosed aspects include a method for deriving IIR filter coefficients for sound recreation from a secondary sample corresponding to a main sample, comprising: transforming secondary sample and main sample from time domain to frequency domain to generate secondary frequency spectrum magnitude and main frequency spectrum magnitude; calculating a magnitude difference from the secondary frequency spectrum magnitude and main frequency spectrum magnitude; extracting an envelope from the magnitude difference; warping the envelope by scaling it onto a mel scale to obtained a warped envelope; applying Yule-Walker equations to the warped envelop to obtain polynomial coefficients; converting the polynomial coefficients from mel scale to linear scale to obtain IIR filter coefficients. In embodiments, converting the polynomial coefficients from mel scale to linear scale comprises rotating each pole and zero of the IIR filter. Additionally, in embodiments, the method further comprises smoothing the magnitude difference prior to extracting the envelope. In embodiments applying Yule-Walker equations may comprise using Yule-Walker coefficients to a plurality of filter orders.

Disclosed aspects further include audio sampler, comprising a sample library having stored therein a plurality of main audio samples and a plurality of infinite impulse response (IIR) coefficients divided into subset, each subset corresponding to one of the main audio samples; a sample playback engine comprising an input receiving the main audio samples and outputting a playback signal; and, an IIR filter receiving the corresponding subset of IIR coefficients and applying the IIR filter to the main audio samples or to the playback signal.

### BRIEF DESCRIPTION OF THE DRAWINGS

The patent or application file contains at least one drawing executed in color. Copies of this patent or patent application publication with color drawings will be provided by the Office upon request and payment of the necessary fee.

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1A is a plot of an example of audio signal without zero-padding, while FIG. 1B is a plot of the audio signal with zero-padding, according to disclosed embodiments.

FIG. 2 is a plot of spectral envelope with IR magnitude, showing IR magnitude spectrum (in black) and its spectral envelope (in red), according to disclosed embodiments.

FIG. 3A is a plot illustrating the approximation filter magnitude (pink) obtained from the envelope signal without using frequency warping (blue), according to disclosed embodiments.

FIG. 3B is a plot illustrating the envelope plotted in red and the warped envelop plotted in blue, according to disclosed embodiments.

FIG. 4 is a plot illustrating filter approximation without frequency warping, the envelop signal plotted in blue and the approximation filter magnitude plotted in pink, according to disclosed embodiments.

FIG. 5A illustrates a plot of the unwarped filter magnitude (pink) overlayed on top of the warped envelope (blue), according to disclosed embodiments.

FIGS. 5B-5D are plots showing the results of applying the Yule-Walker approximation filter using different filter orders, wherein FIG. 5B is a plot of third-order unwarped filter, FIG. 5C is a plot of a sixth-order unwarped filter, and FIG. 5D is a plot of a tenth-order unwarped filter, according to disclosed embodiments.

FIG. 6 illustrates an example of basic steps in converting high harmonic content (Loud) audio samples into virtual low harmonic content (Soft) samples with realistic accuracy through an IIR process, according to disclosed embodiments.

FIG. 6A illustrates an example of applying a single PP Coefficient to affect an entire virtual music instrument by inserting one IIR filter at the audio output of the sample playback engine, according to disclosed embodiments.

FIG. 7 is a flow chart illustrating the basic steps in converting the normal sound of a recorded musical instrument into its various forms of muted sounds with realistic accuracy through an IIR process, according to disclosed embodiments.

FIGS. 8A and 8B illustrate examples for arrangement of a standard mapped sample set and a mapped IIR filter set, respectively, for a keyboard, according to disclosed embodiments.

FIGS. 9A and 9B illustrate an embodiment wherein the samples of one instrument can be modified to generate the sound of a different instrument or different character.

FIG. 10 illustrates a block diagram of a process of converting an existing mapped sample library to a mapped IIR filter library, according to disclosed embodiments.

FIG. 11 illustrates an example of transforming one type of human voice sound into another, using an IIR process according to embodiments.

FIG. 12 illustrates an example of transitioning from loud portion of sample to soft portion of sample over time using embodiments of the IIR process.

FIG. 13 is a flow chart illustrating one example of a process that may be executed by a processor to generate the filter coefficients.

FIG. 14 illustrates using embodiments of the IIR process within music synthesizers for creating unique and continuously variable waveforms over time.

### DETAILED DESCRIPTION

Embodiments of the inventive IIR filter processing will now be described with reference to the drawings. Different embodiments or their combinations may be used for different applications or to achieve different benefits. Depending on the outcome sought to be achieved, different features disclosed herein may be utilized partially or to their fullest, alone or in combination with other features, balancing advantages with requirements and constraints. Therefore, certain benefits will be highlighted with reference to different embodiments, but are not limited to the disclosed embodiments. That is, the features disclosed herein are not limited to the embodiment within which they are described, but may be “mixed and matched” with other features and incorporated in other embodiments.

In the context of this disclosure, the following applies:

Infinite impulse response (IIR) is a property applying to many linear time-invariant systems that are distinguished by having an impulse response that does not become exactly zero past a certain point but continues indefinitely.

IIR filter is an analog or digital filter. The presence of feedback in the topology of a discrete-time filter generally creates an IIR response. The z domain transfer function of an IIR filter contains a non-trivial denominator, describing those feedback terms. Thus, digital IIR filters can be based on well-known solutions for analog filters such as the Chebyshev filter, Butterworth filter, and elliptic filter, inheriting the characteristics of those solutions.

The term target refers to an actual audio sample the system aims to simulate, while simulated target refers to the output signal that results from the IIR filtering of the signal so as to simulate the target.

Dynamic level refers to any of the musical terms for an instrument's specific volume and its associated timbre (e.g. fortissimo, pianissimo, etc.). Dynamic layer refers to any recording of a specific audio sample of an instrument at a specific volume and timbre at a specific dynamic and with a specific playing style.

The Yule-Walker equations are a set of linear equations used in the field of statistics and signal processing to estimate the coefficients of an autoregressive (AR) model. An AR model is a type of time series model that expresses a variable of interest as a linear combination of its own past values. The method involves solving a set of linear equations that relate the autocorrelation function (ACF) of the process to the AR coefficients.

A sample playback engine is a software or hardware component that plays back digital audio samples. It is commonly used in music production and sound design to create realistic instrument sounds. The engine reads the audio samples from a storage medium (sample library), such as a hard drive or solid-state drive, and plays them back at the desired pitch and tempo.

A window function is a mathematical function that is zero-valued outside of some chosen interval. Typically, window functions are symmetric around the middle of the interval, approach a maximum in the middle, and taper away from the middle.

In order to provide a complete solution, disclosed embodiments enable both generating a sample library with reduced footprint and enable rapid recreation of the sounds from an IR library, an IIR library, or an output of a synthesizer, to enable live performance without latency. The disclosure of the embodiments starts with the creation of the sample library and, more specifically, with the process of deriving the coefficients for the IIR filter.

In the following description, embodiments are disclosed which enable drastic reduction in the footprint of an audio sample library by eliminating the bulk of the samples and simulating them with an IIR filter. As noted, disclosed embodiments utilize a time-wise short length audio sample called the “target” sample. It is typically a sample of a music instrument, a human voice, or sound effect, but not limited to any particular type of instrument or sound. The target sample is used to generate a setting for a specific type of multi-pole audio filter, called an IIR (Infinite Impulse Response) filter. The IIR filter is then applied to a “destination” audio sound, thereby transforming the destination sound into the timbral sonic characteristics of the target sampled sound.

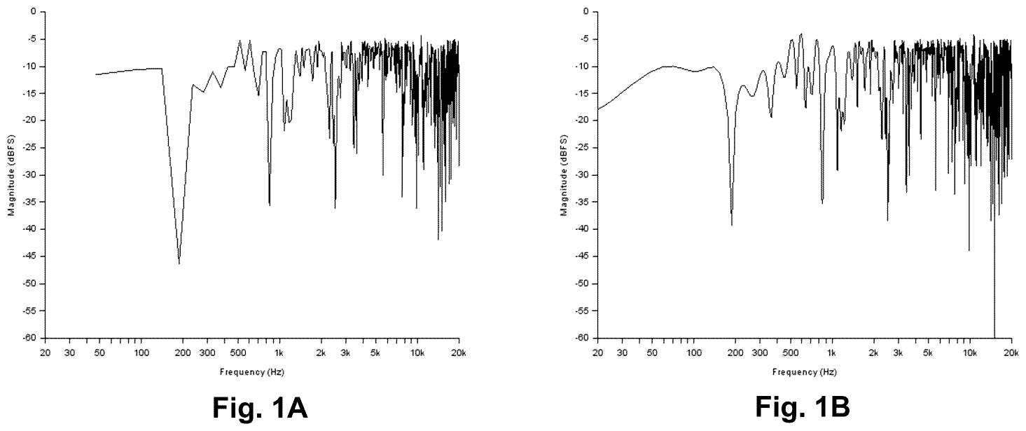

Process steps that may be performed according to various embodiments may include the following. One process step involves the spectrum computation of the audio signal. In this step Fourier transform is used to compute the magnitude spectrum of the impulse response. A Fourier transform takes a signal that exists in the time domain and represents it in the frequency domain. If an audio signal normally exists as series of amplitudes (amplitudes are values that are generally contained within a normalized range [−1, 1] that represent the position in an oscillating waveform) over some period of time, the Fourier transform will give the frequencies that exist over that same time period with their magnitude (how much of that value exists). A magnitude spectrum is a representation of how the frequencies in a signal change over time. An impulse response, or IR, in signal processing is the output of a dynamic system when presented with a brief input signal. In this embodiment, by adding trailing zeros (“zero-padding”) to the IR we get more points in the magnitude spectrum, that is especially useful for low frequencies. FIG. 1A is a plot of the impulse response signal without zero-padding, while FIG. 1B is a plot of the audio signal with zero-padding. As can be seen, the plot of FIG. 1B contains more information, especially in the low frequencies below 200 Hz.

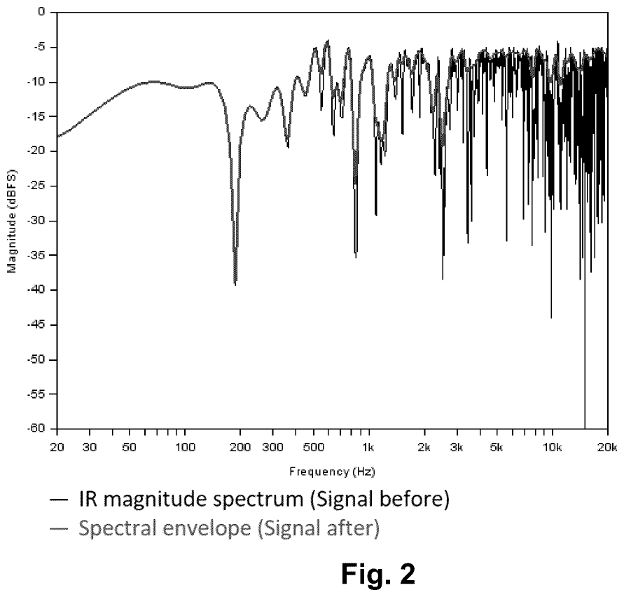

Another step in the disclosed embodiments is extracting an envelope. An envelope describes how audio changes over time. In this case we care about how the amplitude changes in our sample. In one example, we compute the envelope by taking the absolute value of each 1/16th octave band (an octave band is a range of frequencies that span a whole octave). Then the result is smoothed using a running 1/16th octave Gaussian window. A windowing function in signal processing is used to reduce noise (randomness) in a signal so we can isolate its key components. A Gaussian window in this case is a specific type of smoothing that achieves a more balanced signal to noise ratio. This allows us to have a much simpler curve to approximate especially in the high frequencies. This is illustrated by the plot of FIG. 2, wherein the IR with zero-padding of FIG. 1B is plotted in black, while the signal after the application of spectral envelope is plotted in red.

A further step in disclosed embodiment is isolating trends in the frequency data using frequency warping. An autoregressive model is used to find trends in seemingly random data. This example uses the Yule-Walker equations to isolate a trend of frequency data in the impulse response. The implementation of the Yule-Walker algorithm described herein approximates the curve on a linear frequency axis. The Yule-Walker equations are a form of an autoregressive model. Because we are working with audio and humans hear frequencies on a logarithmic axis, we use a “frequency warping” technique to simulate how the logarithmic curve looks on a linear axis. Doing this removes frequencies that are inaudible to the human ear and would just generate noise in our IR. Without this step, the algorithm would approximate high frequencies very well but the approximation for low/mid frequencies would be very poorly viewed on a log frequency axis.

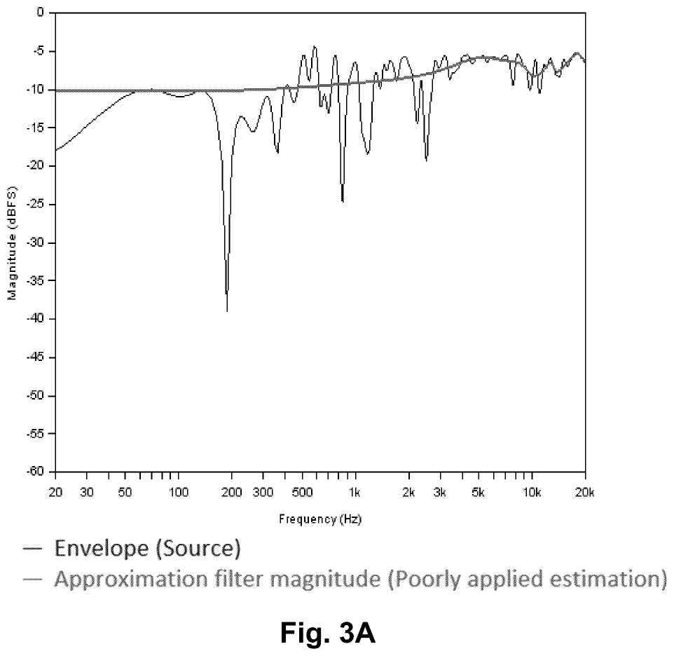

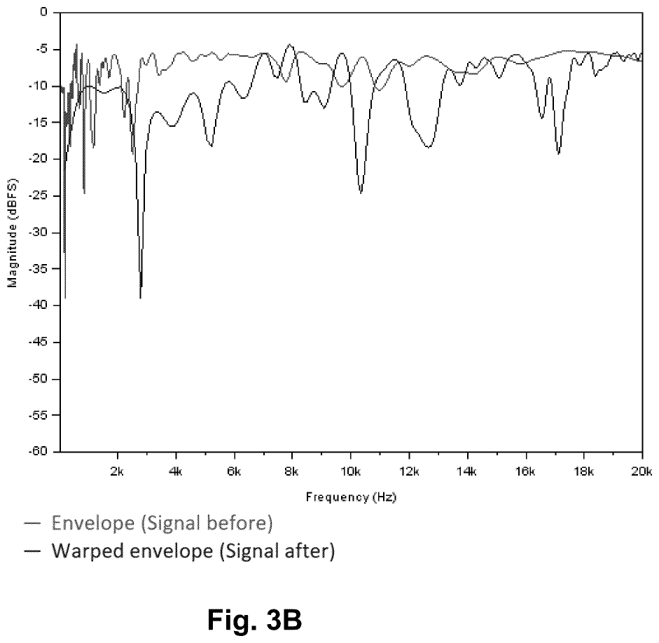

FIG. 3A illustrates the plot of the approximation filter magnitude (pink) obtained from the envelope signal—as shown in FIG. 2—without using frequency warping (blue). As can be seen the approximation is very poor, especially at the lower and mid frequencies. Conversely, FIG. 3B illustrates a plot of the envelope signal (in red) and the warped envelope (blue plot). Note that the frequency scale in the x-axis of FIG. 3B is linear, so that the plot of the envelope signal appears different from how it appears in FIG. 2, in which the frequency scale in the x-axis is non-linear. In sound processing, the mel-frequency cepstrum (MFC) is a representation of the short-term power spectrum of a sound, based on a linear cosine transform of a log power spectrum on a nonlinear mel scale of frequency.

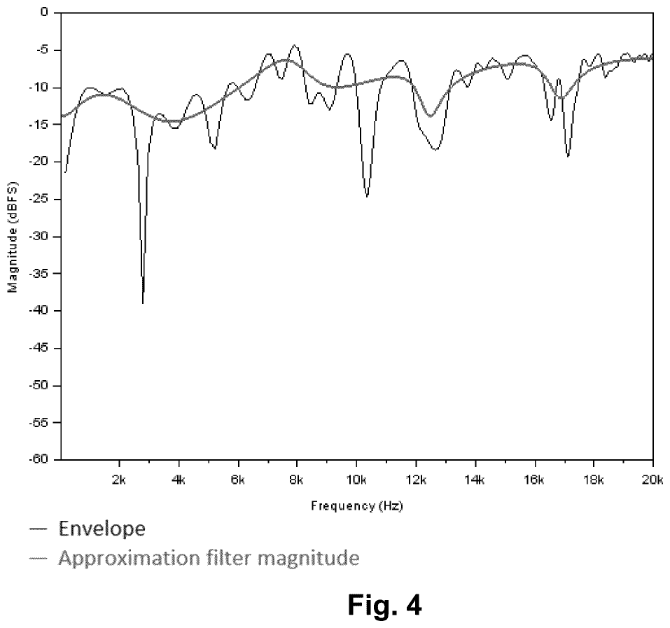

FIG. 4 is a plot of the envelope signal in blue and the approximation filter magnitude resulting from application of a modified Yule-Walker approximation. This step uses the “modified Yule-Walker equations” to compute the best IIR filter of a given order so that its magnitude response matches the envelope as closely as possible. Due to the nature of changing the scaling of the frequencies, we are unable to use the polynomial returned from the Yule-Walker equations directly, and therefore must instead use its coefficients. This method we simply call the “modified Yule-Walker equations”.

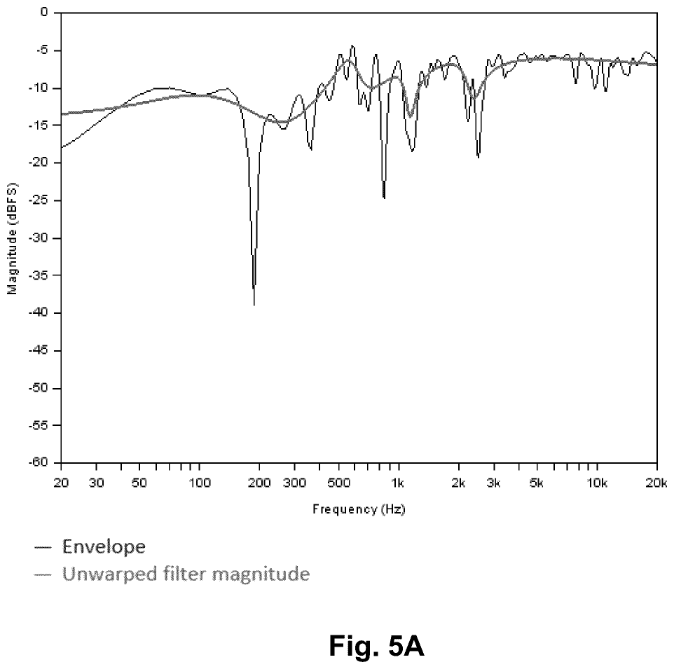

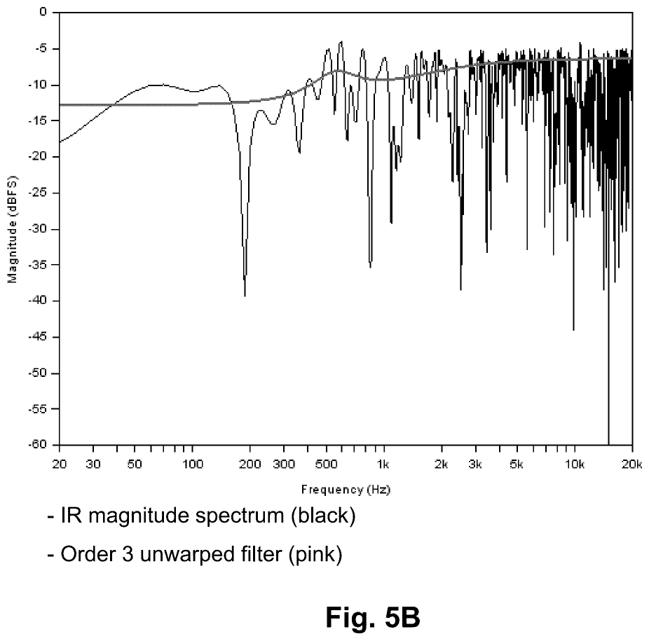

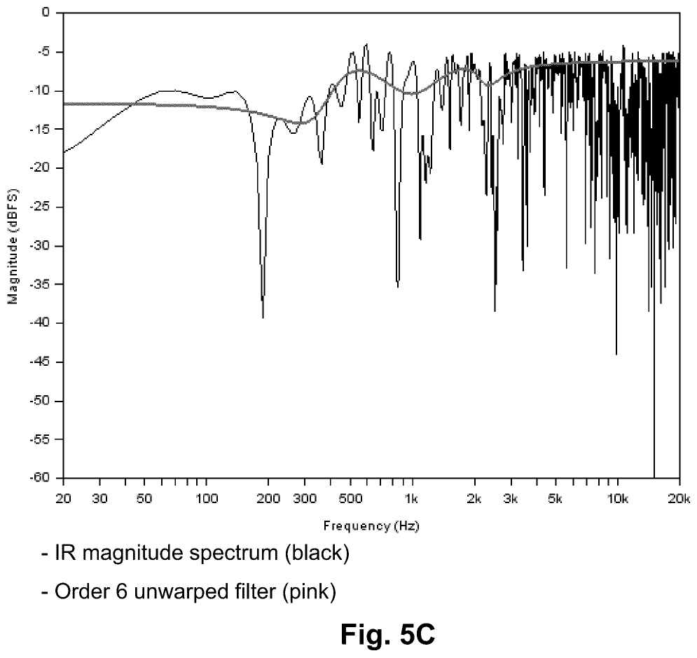

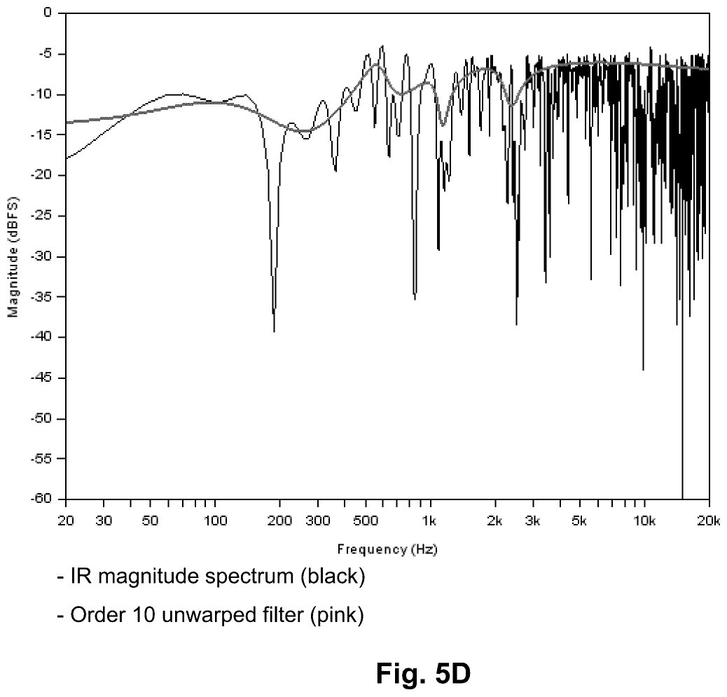

The resulting IIR filter is then approximating the warped envelope of the frequency warping step (FIG. 3B). Because of this, the filter is operating on a different scaling than what is typically expected. We now need to unwarp the filter to get the final result. To do that we rotate each pole and zero of the filter using the warping factor we used to generate the frequency warping. This effectively returns the filter to a linear scaling. FIG. 5A illustrates a plot of the unwarped filter magnitude (pink) overlayed on top of the warped envelope (blue). The graphs of FIGS. 5B-5D are the results of applying the Yule-Walker approximation filter using different filter orders, wherein FIG. 5B is a plot of third-order unwarped filter, FIG. 5C is a plot of a sixth-order unwarped filter, and FIG. 5D is a plot of a tenth-order unwarped filter.

Consequently, disclosed aspects include a method for deriving IIR filter coefficients for sound recreation from a target sample, comprising: transforming target sample from time domain to frequency domain to generate target frequency spectrum magnitude; extracting an envelope from the target frequency spectrum magnitude; warping the envelope by scaling it onto a mel scale to obtained a warped envelope; applying Yule-Walker equations to the warped envelop to obtain polynomial coefficients; converting the polynomial coefficients from mel scale to linear scale to obtain IIR filter coefficients. In embodiments, converting the polynomial coefficients from mel scale to linear scale comprises rotating each pole and zero of the IIR filter. Additionally, in embodiments, the method further comprises smoothing the target frequency spectrum magnitude prior to extracting the envelope. In embodiments applying Yule-Walker equations may comprise using Yule-Walker coefficients to a plurality of filter orders. Transforming target sample may be done by applying a Fourier transform and zero-padding the IR response. Extracting the envelope may include dividing the target frequency spectrum magnitude into sub-octave bands and applying a window function to smooth each sub-octave band.

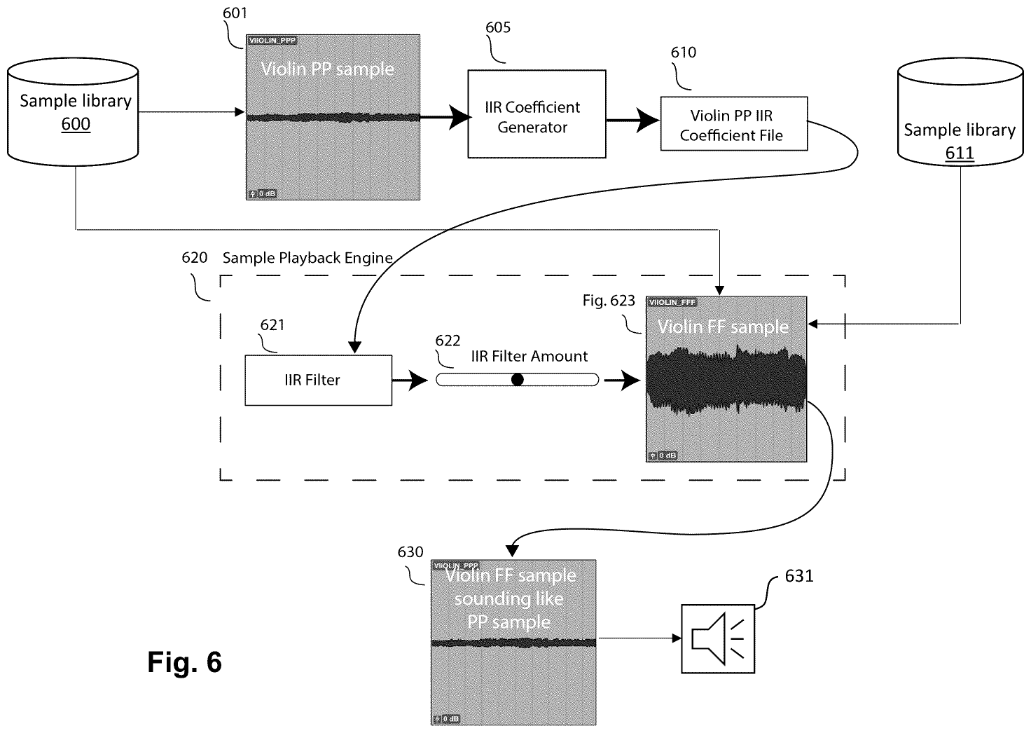

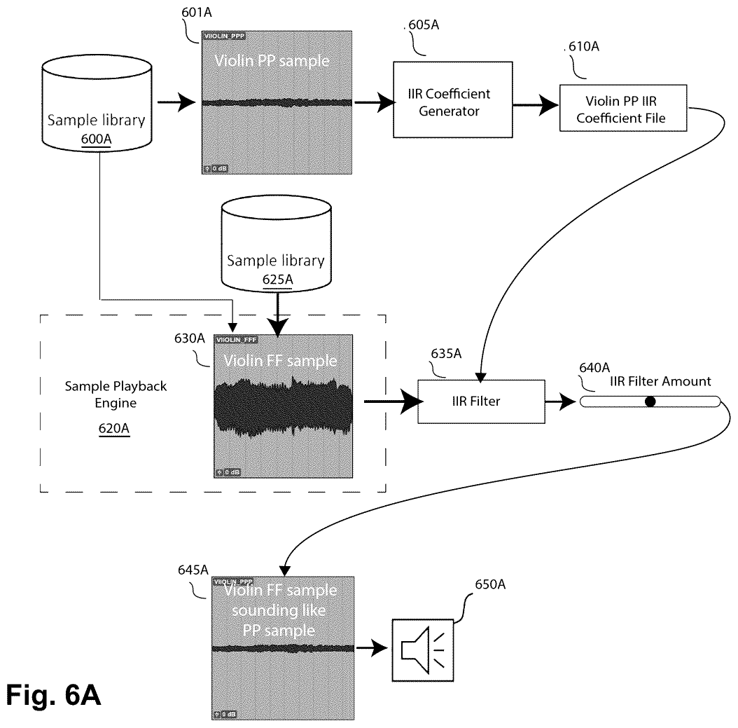

FIG. 6 illustrates an example of basic steps in converting high harmonic content (Loud) audio samples into virtual low harmonic content (Soft) samples with realistic accuracy through an IIR process, according to disclosed embodiments. The specific example illustrated in FIG. 6 relates to violin samples, but the process steps are equally applicable to any other audio sample. The purpose of the process in this example is to reduce sample storage footprint and RAM requirements by exchanging the “real” soft sounding samples, known as PP samples, with their PP IIR coefficients that are read by an IIR filter for processing their Il sample counterparts to sound the same. The advantage of ultimately eliminating the PP samples is storage and processing saving, e.g., it allows for faster sample library download times from the Internet. The disclosed IIR process can use less CPU power than streaming “real” PP samples, and it frees up half the HD (hard drive storage) footprint. In addition, the same IIR coefficients can be used to transform similar instruments' FF samples, such as two or more trumpets that can use the exact same PP IIR coefficients, thereby reducing hardware requirements and Internet download times even further.

A sample library 600 consists of recorded (sampled) music instruments. Each sampled instrument library consists of all its types of sounds it can make, all the pitches these sounds can produce, and most importantly for this example the various dynamic (loud to soft) levels each sound variation can produce. The loudest level is FF (Fortissimo) meaning loudest in the industry standard Italian music terminology. The softest is PP (Pianissimo) meaning softest in Italian music terms. Since there are thousands of samples in every sound library, generating the PP IIR coefficients and storing the coefficients instead of the actual PP samples would save a tremendous amount of storage space. Moreover, recreating the PP sound from the FF sound using the disclosed method is done on-the-fly and in real-time and generates a highly accurate representation of the originally recorded sample.

In step 601 a real PP audio sample (here, a PP violin sample—soft volume and timbre) is obtained from, for example, a sampler or a sample library 600. Typically, in a sample library 600 there will be as many discrete PP note pitch samples as there are discrete FF note pitch samples. In embodiments, each corresponding PP note pitch sample will be processed individually for generating their own, unique, PP IIR Coefficients. Once the PP IIR coefficients are created, e.g., using any of the embodiments disclosed herein, the original PP samples, i.e., the targets, are no longer needed.

In step 605 the PP sample is fed into an IIR Coefficient Generator. This generator can be made in the form of either computer programming or in the form of electronic hardware circuitry. In step 610 the IIR coefficient generator outputs a PP IIR Coefficient file and/or a form of programming instructions for electronic hardware circuitry that corresponds to the coefficients—thus reference herein to “coefficient” is meant to cover both possibilities. This output can be stored in the sample library 611 (which may be the same as library 600) instead of the actual PP sample, thereby saving storage space and drastically reducing the size of the sample library.

Thus, by the disclosed embodiments, a method for constructing an audio sample library stored in a digital form is provided, comprising: obtaining a plurality of main samples, each main sample corresponding to a respective sound, and storing the plurality of main samples in digital form; generating a set of infinite impulse response (IIR) coefficients derived from at least one secondary sample different from any of the main samples, the set of IIR coefficients applicable to IIR filter to modify dynamic level of selected main sample from the plurality of main samples; storing the set of IIR coefficients to thereby form the audio sample library having plurality of main samples and a set of IIR coefficients. In embodiments, the secondary sample(s) has a different dynamic level of any of the plurality of main samples.

In the example of FIG. 6, the IIR filter used for reading and actuating the IIR coefficients is built into the sample playback engine 620. At step 621 the sample playback engine 620 reads and actuates IIR filter 621 processing of the Violin FF sample 623 to make it sound like the PP sample 630. (As noted, this example uses violin samples for demonstration purposes only; this process applies to any type of musical instrument and/or sound effect). In FIG. 6 an optional step 622 is illustrated, wherein the IIR filter output can pass through an amount controller (e.g., using a hardware or software fader) prior to processing the FF sample, but instead the system can be preprogrammed for a full amount or to any desired blend amount, which affects how much of the filter effect will be imposed on the FF sample. Including this optional step provides the user with artistic flexibility by adjusting the IIR amount to blend between PP through FF dynamically in real-time. At step 623 a Violin FF sample is selected either from the same library 600 the PP sample was selected from, or from a different library 611 having an FF sample. The selected FF sample can be played by the sample playback engine with or without IIR filter processing activated, or with a blend amount preprogrammed or set in step 622. As shown in step 630, when the IIR filter is fully implemented, the FF sample takes on both the overall volume and timbrel characteristics of the PP sample, such that the audio output of the sample play back engine sounds as if it played the original violine PP sample via audio amplification or monitoring system 631.

Therefore, disclosed embodiments include a sample playback engine, comprising: an input receiving audio samples; an infinite impulse response (IIR) filter having coefficients derived from target samples; a mixer controlling amount of IIR filter applied to the audio samples; and an output providing mixed samples resulting from application of the IIR filter to the audio samples. The mixer of the sample playback engine may be preprogrammed for a preset mixing amount, or may include a user interface for controlling the mixing amount.

FIG. 6A illustrates an example of applying a single PP Coefficient to affect an entire virtual music instrument by inserting one IIR filter at the audio output of the sample playback engine. In this case, elements 660A, 605A, and 610A of FIG. 6A are the same as elements 600, 605, and 610 of FIG. 6, respectively. Here, sample playback engine does not have built-in IIR filters. Instead, an IIR filter 635A is inserted at the sample playback engine audio output and the previously generated PP IIR coefficient is loaded into the IIR Filter as follows. The FF sample(s) to be played is selected from the same library 600A as the PP sample or from a different library 625A of the same type. At step 630A the FF sample(s) is played by the playback engine 620A. At 635A an IIR filter is inserted at the sample playback engine 620A audio output and the previously generated PP IIR coefficient at 610A is loaded into the IIR Filter. Here again an optional manual adjustment can be included in the form of an IIR filter amount controller, such as a mechanical or digital fader. At 645A the result is that the FF sample selected now sound the same as the original Violin PP sound. Notably, this method is merely coarse compared to applying an IIR to each pitch; however, this method serves an economical purpose. At 650A the final audio output can be fed into speakers, headphones, or any other audio device.

By disclosed embodiments an audio sampler is provided, comprising: a sample library having stored therein a plurality of main audio samples and a plurality of infinite impulse response (IIR) coefficients divided into subset, each subset corresponding to one of the main audio samples; and, a sample playback engine comprising an input receiving the main audio samples and outputting a playback signal; and an IIR filter receiving the corresponding subset of IIR coefficients and applying the IIR filter to the main audio samples or to the playback signal.

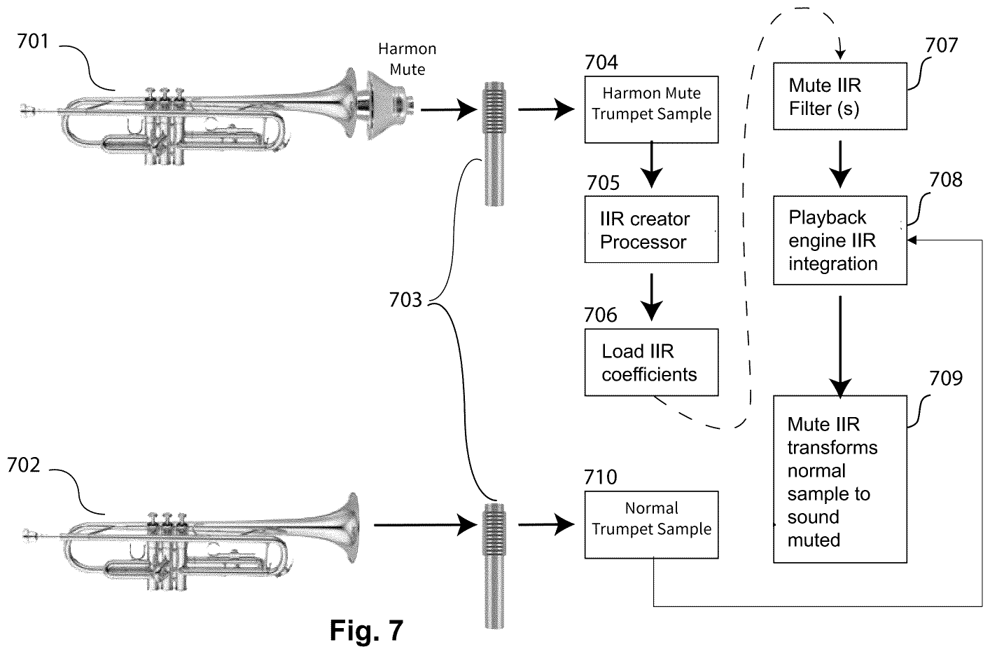

FIG. 7 is a flow chart illustrating the basic steps in converting the normal sound of a recorded musical instrument into its various forms of muted sounds with realistic accuracy through an IIR process. Instrument mutes are relatively small mechanical devices that the musician attaches to the instrument to alter its sound. Mutes are in fact a type of mechanical equalizer, much in the way a recording engineer might apply an Equalizer (EQ) to human voice to make it sound like a voice on telephone. Mutes as well as EQ cannot add artificial harmonics to a sound, only subtract or boost the existing harmonics in various frequency bands to alter the sound.

Many types of musical instruments including brass, wind, and string instruments have a barrage of mute selections designed to produce specific harmonic content profiles depending on their needs. For instance, a Harmon mute produces a pinched, nasal, sound commonly associated with jazz. A Hush mute, as the name suggests, produces a mellow sound. Similarly, string instruments have Con Sordino and Practice mutes that generate much of the same sonic qualities as the Hush mute does for brass instruments. It is important to keep in mind: one of the benefits of the disclosed IIR process is that it allows users to experiment by applying the IIR profiles generated on one type of instrument, or even a sound effect or human voice, literally any sound, onto another type of instrument entirely, thereby creating totally brand-new sounds that would be impossible to reproduce in the physical world. For example, using the disclosed IIR process, one can apply a trumpet Harmon mute onto an electric bass guitar. Such a combination cannot be made in the physical world.

FIG. 7 depicts a trumpet 701 with a Harmon mute attached at the end of the instrument known as the bell. In step 703 both the trumpet without the mute 702 and the muted trumpet 701 are first recorded separately. Typically, the musician records every pitch the instrument can physically produce, starting with its lowest pitch on up to its highest; typically, 30 to 50 separate pitches in total. Once each recorded pitch from both the muted Trumpet 701 and the normal Trumpet 702 is recorded, the pitches are then edited into discrete recordings known as samples, 704 and 710, respectively. In step 705 the muted samples are either individually or batch processed into discrete IIR coefficients. The discrete IIR coefficients are named and exported into a folder and stored in preparation for the next step. In this example, in step 706 each discrete IIR coefficient is loaded into their own, separate, IIR filter application; typically, but not limited to, one IIR application for each pitch of the instrument. This results in muted IIR filters 707. As explained with respect to FIGS. 6 and 6A, the IIR filter can be integrated with the playback engine to provide a per-note IIR filter implementation, as illustrated in 708, or can be placed at the output end of the audio chain (as illustrated in FIG. 6A). In 709 the normal sample is transformed by the IIR filter to have the dynamic level of a Harmon mute sample.

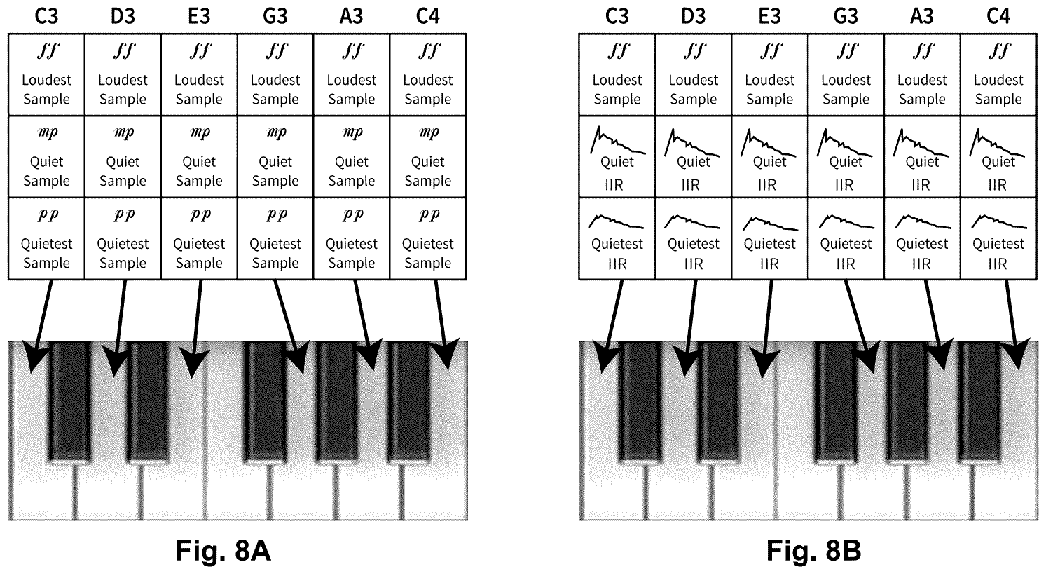

FIGS. 8A and 8B illustrate examples for arrangement of a standard mapped sample set and a mapped IIR filter set, respectively, for a keyboard, according to disclosed embodiments. FIG. 8A illustrates three samples, ff, mp, and pp, for each key indicated by arrow (although in reality all keys would be sampled). Conversely, FIG. 8B illustrates the library constructed according to the disclosed embodiments, wherein for each pitch of each key, the loudest sample is stored, together with the corresponding IIR filter coefficients of the quiet and quietest samples. Thus, when a pitch is to be sound, e.g., quiet sample E3, the IIR filter of the quiet E3 and the sample of the loudest E3 are processed to recreate the sound of a sampled quiet E3. As can be understood, since all of the quiet and quietest samples have been eliminated, the library of FIG. 8B is much lighter than that of FIG. 8A.

Thus, by the disclosed embodiments, a method for constructing an audio sample library stored in a digital form is provided, comprising: obtaining a plurality of main samples, each main sample corresponding to a respective sound, and storing the plurality of main samples in digital form; generating a set of infinite impulse response (IIR) coefficients derived from at least one secondary sample different from any of the main samples, the set of IIR coefficients applicable to IIR filter to modify dynamic level of selected main sample from the plurality of main samples; storing the set of IIR coefficients to thereby form the audio sample library having plurality of main samples and a set of IIR coefficients; wherein generating the set of IIR coefficients is derived from a plurality of secondary samples yielding a plurality of subsets of IIR coefficients, each of the subsets corresponding to one of the main samples. In the method, each of the plurality of main samples may be obtained by recording a note played by a musical instrument, and each of the plurality of secondary samples is obtained by recording a note played by the same musical instrument of the corresponding main sample. Also, in the method each of the plurality of main samples comprises a recording of a note played by a musical instrument, and each of the plurality of secondary samples is obtained by recording of the same note of the corresponding main sample. By the disclosed method, the audio sample library comprises an M×N matrix having M main samples and N subsets of IIR coefficients, wherein N=iM, wherein i is a positive integer equal to or larger than 1.

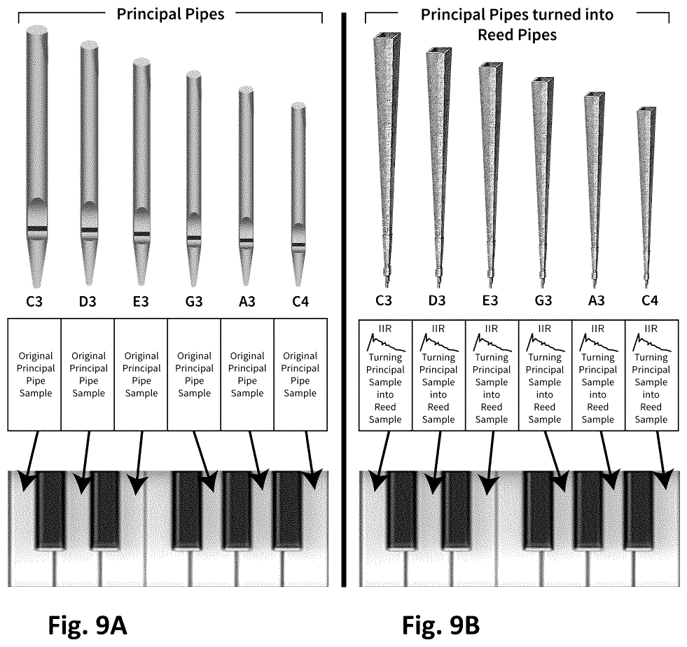

FIGS. 9A and 9B illustrate an embodiment wherein the samples of one instrument can be modified to generate the sound of a different instrument or different character. FIG. 9A illustrates a sample library of the principle sounds of the organ keys recorded using the flue pipes, e.g., the Signal fff for each note. FIG. 9B illustrates an IIR library of the corresponding IIR filters generated for each of the notes, but which store the sound characteristic (i.e., IIR coefficients) of Reed Pipes. A reed pipe is sounded by a vibrating brass strip known as a reed, as opposed to flue pipes, which produce sound solely through the vibration of air molecules. Thus, the sound character of a reed pipe is different from that of a flue pipe. However, rather than storing the fff ordinario sound for each note of the reed pipes, this embodiment makes use of the fff ordinario sound of the corresponding flue pipe. Then, for each note of the reed pipe, the corresponding fff ordinario sound of the flue pipe is processed with an IIR filter of the reed pipe, to generate a target sample of a reed pipe. In this sense, the first instrument is processed through the IIR filter of a second instrument, to generate the sound of the second instrument, thus not requiring storing samples of the second instrument.

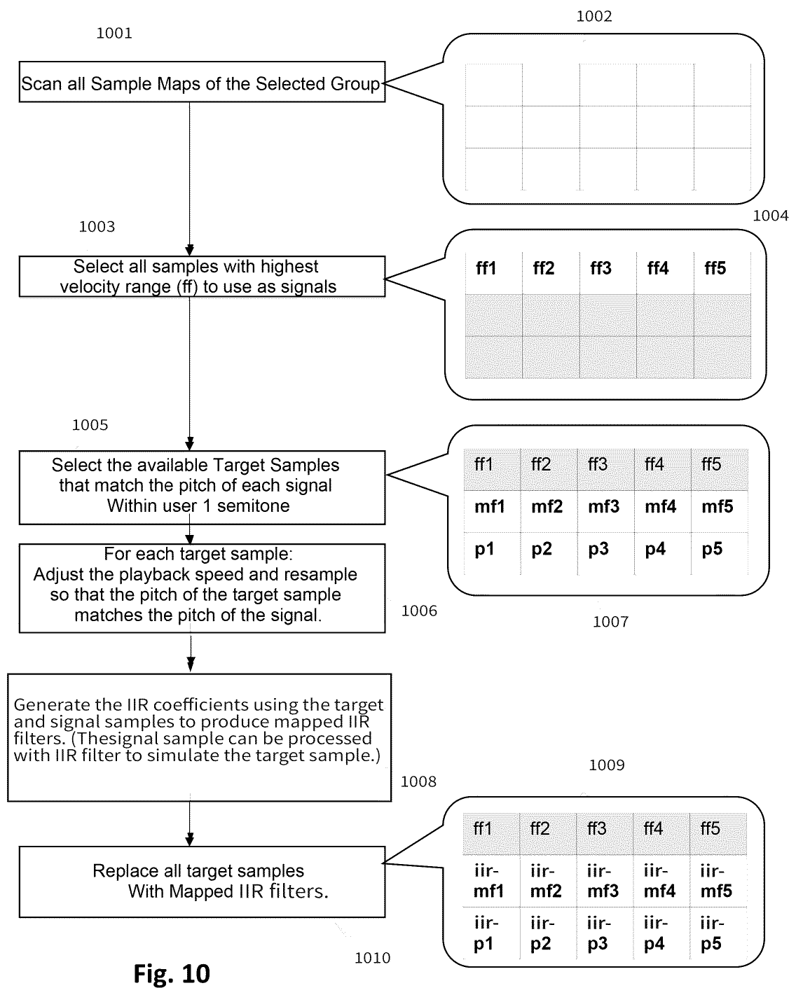

FIG. 10 illustrates a block diagram of a process of converting an existing mapped sample library to a mapped IIR filter library, according to disclosed embodiments. The IIR filter processes of the disclosed embodiments can be used to build a sample library for use during performance or recording. Of course, the IIR filter process can also be used to convert an existing sample library to an IIR filter library according to the disclosed embodiments.

In step 1001 all the samples mapped in 1002 are scanned and in 1003 all the samples with the highest velocity range (i.e., having the most dynamic information) are selected. In this example the ff (fortissimo) samples are selected for each note and for each instrument. Each of these samples, ff1, ff2, ffn, will be designated as the Signal when performing the IIR generation (and thereafter when performing the IIR filter for playback). The arrangement graphically illustrated in 1004, wherein the top row represents storage of each fortissimo sample for each note and/or instrument—M samples in the M×N matrix. For each of the fortissimo notes a series of corresponding IIR filter will be calculated and stored in a mapped fashion, to complete the M×N matrix as follows.

In 1005 a first Target sample is selected, say a Target sample corresponding to Signal ff1. Sometimes the Target will have the exact same pitch as the Signal, but that is not always the case. Therefore, in 1005 an allowance is made up to half tone higher or lower than the Signal. Then in 1006 if the pitch does not match exactly, the playback speed of the Target is slowed down or speed up so that it matches the pitch of the corresponding Signal. Once the pitch of the Target matches that of the Signal, in 1008 the IIR generation process is performed using any of the methods disclosed herein, to generate the IIR filter, which is stored in a mapped fashion, as shown in 1009. This process is repeated until in 1010 all the original samples, other than the selected samples corresponding to the Signal, are replaced by N corresponding mapped IIR filters.

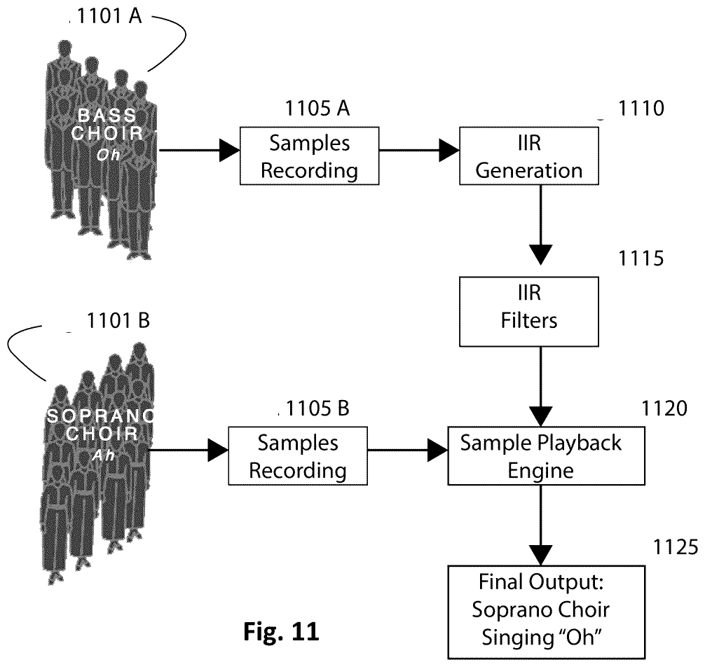

FIG. 11 illustrates an example of transforming one type of human voice sound into another, using an IIR process according to embodiments. In this example we take a sampled choir singing an “Oh” sound and then IIR filter the corresponding pitches of a sampled female choir singing “Ah”. The result is the female choir takes on the “Oh” sound from the male choir; solo voices can be processed this way just as easily. In 1101A an audio recording is made of all pitches that the male choir can produce. In this example we are using a male bass choir singing “Oh”. In 1101B a separate audio recording is made of all pitches that the female choir can produce. In this example we are using a female soprano choir singing “Ah”. The individual pitches are edited into discrete sample recordings that are individually named and stored into “Oh” and “Ah” folders 1105A and 1105B, respectively. In 1110 the “Oh” samples are IIR processed to derive the IIR coefficients. It is not required to derive “Ah” samples' coefficients unless they are to be used to IIR filter other instruments down the line. The “Oh” IIR coefficients are loaded into the sample playback engine's IIR filters in 1115, and in 1120 the filters are applied to the “Ah” samples of 1105B to output soprano choir “Oh” sound in 1125.

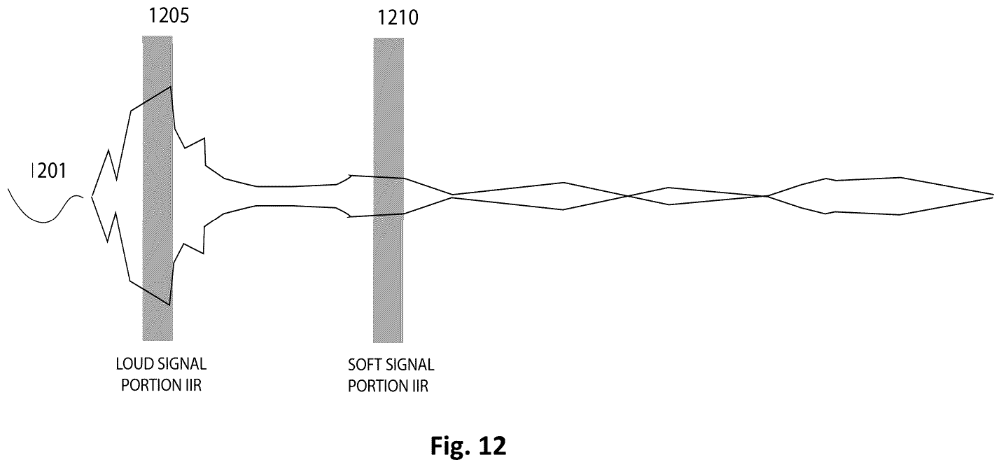

FIG. 12 illustrates an example of transitioning from loud portion of sample to soft portion of sample over time using embodiments of the IIR process. In this example we show how a sample can have a loud portion, typically the front of the sample known as the “Attack,” and the soft portion of the sample known as the “Sustain.” For example, a bass note played with a pick will have a harsher attack than the same note plucked with a finger. In this instance, it sometimes becomes necessary to lessen the harsh effect of the attack portion by taking the soft portion IIR and IIR filter the front portion to create a smoother and consistent overall sound. In this example 1201 depicts the entire length of time duration of the sample, while 1205 depicts the loud portion from which an IIR can be generated for further use and 1210 depicts the soft portion of the sample and for this example it will be used to create the IIR coefficient that will be placed over the front portion 1205 of the waveform. There are several methods by which the soft sound IIR can be applied to the front of the sample and then gradually removed over time span until it reaches the time position by which the soft IIR was generated. One method is to use a timer. Another method is to use a common synthesizer envelope generator. In the end, the user can determine how much of the soft IIR filter coefficient to apply at the beginning of the sample while also determining at what point in time the IIR filter is no longer needed during the sample playback.

Thus, by the disclosed embodiments, a method for constructing an audio sample library stored in a digital form is provided, comprising: obtaining a plurality of main samples, each main sample corresponding to a respective sound, and storing the plurality of main samples in digital form; generating a set of infinite impulse response (IIR) coefficients derived from at a plurality of secondary samples, the set of IIR coefficients applicable to IIR filter to modify dynamic level of selected main sample from the plurality of main samples; storing the set of IIR coefficients to thereby form the audio sample library having plurality of main samples and a set of IIR coefficients, wherein each of the plurality of main samples is obtained by recording a note played by a musical instrument, and each of the plurality of secondary samples is obtained by time-truncating the note of a corresponding main sample.

Also, by disclosed embodiments, a method for constructing an audio sample library stored in a digital form is provided, comprising: obtaining a plurality of main samples, each main sample corresponding to a respective sound, and storing the plurality of main samples in digital form; generating a set of infinite impulse response (IIR) coefficients derived from at a plurality of secondary samples yielding a plurality of subsets of IIR coefficients, each subset of IIR coefficients is derived from a truncated section of the corresponding main sample, each of the subset of IIR coefficients applicable to IIR filter to modify dynamic level of selected main sample from the plurality of main samples; storing the set of IIR coefficients to thereby form the audio sample library having plurality of main samples and a set of IIR coefficients,

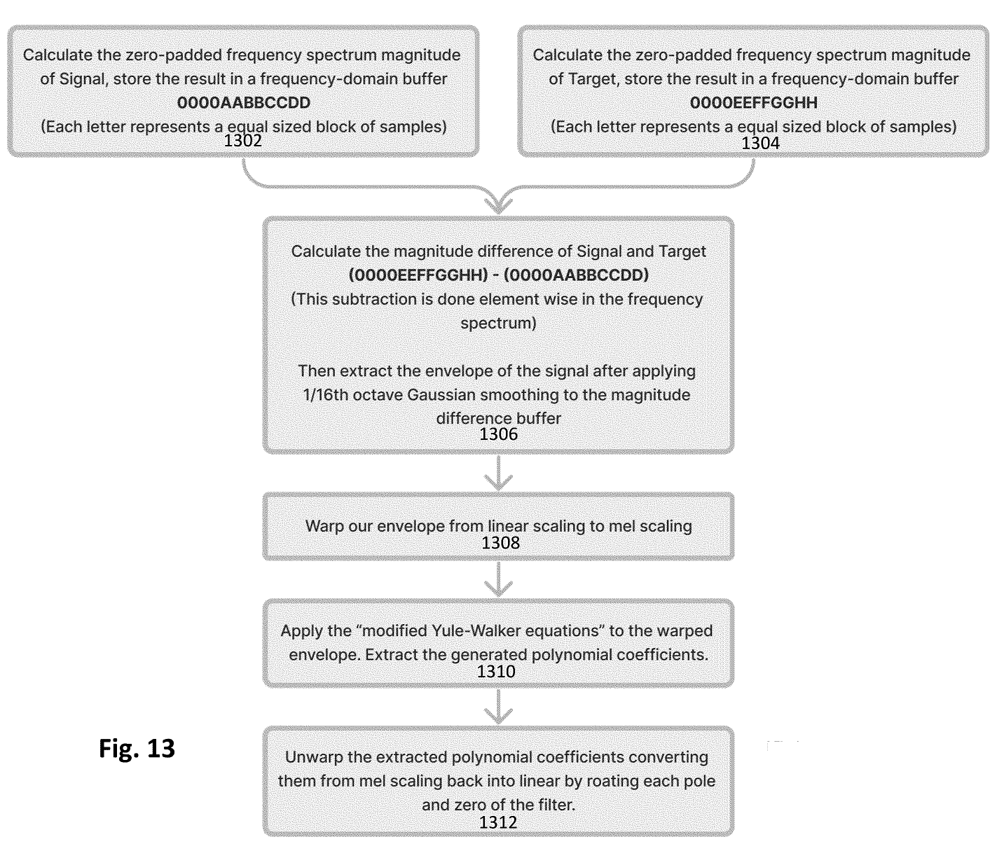

FIG. 13 is a flow chart illustrating one example of a process that may be executed by a processor to generate the filter coefficients. Two audio samples are obtained, e.g., the same note played by a cello recorded loud and soft, the same note played once by piano and once by organ, etc. One sample is designated as Signal and one sample is designated as Target. In 1302 the zero-padded frequency spectrum magnitude of the Signal is calculated, and the result is stored in the frequency domain buffer as, e.g., 0000AABBCCDD, wherein each letter represents an equal sized block of samples. In 1304 the zero-padded frequency spectrum magnitude of the Target is calculated, and the result is stored in the frequency domain buffer as, e.g., 0000EEFFGGHH, wherein each letter represents an equal sized block of samples. In 1306, the magnitude difference of Signal and Target is calculated element wise in the frequency spectrum. Then, extracting the envelope of the signal after applying 1/16^{th} octave Gaussian smoothing to the magnitude difference buffer. At 1308 a warp is applied to the envelope from linear scaling to mel scaling, and the modified Yule-Walker equations are applied to the warped envelope. The generated polynomial coefficients are then extracted. The extracted polynomial coefficients are then unwarped, thereby converting them from mel scaling back to linear scaling by rotating each pole and zero of the filter.

Thus, disclosed embodiments provide a method for constructing an audio sample library stored in a digital form, comprising: obtaining a plurality of main samples, each main sample corresponding to a respective sound, and storing the plurality of main samples in digital form; generating a set of infinite impulse response (IIR) coefficients derived from at least one secondary sample different from any of the main samples, the set of IIR coefficients applicable to IIR filter to modify dynamic level of selected main sample from the plurality of main samples; storing the set of IIR coefficients to thereby form the audio sample library having plurality of main samples and a set of IIR coefficients, wherein generating a set of infinite impulse response (IIR) coefficients comprises applying Yule-Walker equations to a representation of each of the main samples. In the method, the representation of each of the main samples may be obtained by removing frequencies that are inaudible to human ear.

Additionally, disclosed embodiments provide a method for deriving IIR filter coefficients for sound recreation from a secondary sample corresponding to a main sample, comprising: transforming secondary sample and main sample from time domain to frequency domain to generate secondary frequency spectrum magnitude and main frequency spectrum magnitude; calculating a magnitude difference from the secondary frequency spectrum magnitude and main frequency spectrum magnitude; extracting an envelope from the magnitude difference; warping the envelope by scaling it onto a mel scale to obtained a warped envelope; applying Yule-Walker equations to the warped envelop to obtain polynomial coefficients; converting the polynomial coefficients from mel scale to linear scale to obtain IIR filter coefficients. In embodiments, converting the polynomial coefficients from mel scale to linear scale comprises rotating each pole and zero of the IIR filter. Additionally, in embodiments, the method further comprises smoothing the magnitude difference prior to extracting the envelope.

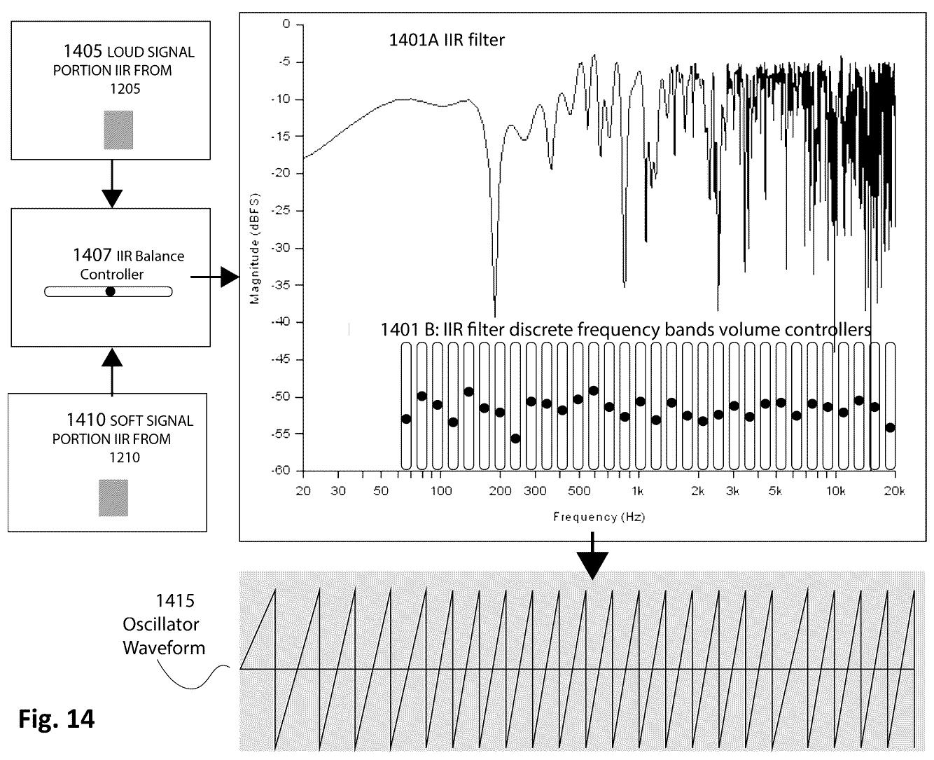

FIG. 14 illustrates using embodiments of the IIR process within music synthesizers for creating unique and continuously variable waveforms over time. In continuation of the process described with reference to FIG. 12, embodiments of the IIR process can be applied just as easily onto a conventional synthesizer oscillator in lieu of a sampled waveform. When used correctly, it is possible to come very close to imitating live instruments without the need for an extensive HD footprint of sampled sounds. Conventional music synthesizers are confronted by two main obstacles: live musicians perform with a high degree of sound variation as they play, known as human factor. This is the reason why professional composers opt for sampled sounds over synthesizer sounds when writing for virtual instruments. Music synthesizers have been struggling with synthetically generated human factor since their inception. The specific issues are: 1. How to generate from an oscillator a synthetic waveform by altering it over time in an unpredictable manner so that it doesn't sound mechanical—traditionally hard to do, rarely if ever achieved with professional quality. 2. How to provide end-users with hands-on real-time controllability of “humanized” synthetic waveforms so that even the humanization process itself doesn't become predictable—up until now this has been the hardest to achieve of all. These issues may be solved as follows.

The initial setup includes a special IIR filter that provides individual volume control of each frequency band 1401A. This IIR filter includes providing end-users with independent volume controllers for each frequency band, as shown by 1401B. The precise frequency of each band changes dynamically over time. The number of frequency band volume controllers will vary depending on how many controllers the end-users want to have; typically, anywhere from 16 to 34. Users can select a range of frequencies each controller will affect. These frequency band controllers can also be programmed and/or automated to increase or decrease various frequencies over time, for added humanization effect. In this example we use the IIR 1205 from FIG. 12 as the oscillator start time IIR and use the IIR 1210 from FIG. 12 as our oscillator middle time IIR. Reference 1407 indicated the balance controller between the start and middle IIR's. This balance controller can be adjusted manually or programed to progressively blend across both IIR's over time to “create” humanization—this is what conventual synthesizer oscillators cannot do gracefully. Most importantly, there is no limit to the number of cascading IIR settings that can be inserted. The greater the number of IIR variations, the more human, and less predictable, it sounds. The final step is to choose a standard oscillator waveform 1415, such as a sawtooth waveform (shown in this illustration). The IIR filter applied to the oscillator waveform 1415 will create a sense of human playing the note.

Various embodiments were described above, wherein each embodiment is described with respect to certain features and elements. However, it should be understood that features and elements from one embodiment may be used in conjunction with other features and elements of other embodiments, and the description is intended to cover such possibilities, albeit not all permutations are described explicitly so as to avoid clutter.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

What is claimed is:

1. A method for constructing an audio sample library stored in a digital form, comprising:
obtaining a plurality of main samples, each main sample corresponding to a respective sound, and storing the plurality of main samples in digital form;
generating a set of infinite impulse response (IIR) coefficients derived from at least one secondary sample different from any of the main samples, the set of IIR coefficients applicable to IIR filter to modify dynamic level of selected main sample from the plurality of main samples;
storing the set of IIR coefficients to thereby form the audio sample library having plurality of main samples and a set of IIR coefficients.

2. The method of claim 1, wherein the at least one secondary sample has a different dynamic level of any of the plurality of main samples.

3. The method of claim 1, wherein generating the set of IIR coefficients is derived from a plurality of secondary samples yielding a plurality of subsets of IIR coefficients, each of the subsets corresponding to one of the main samples.

4. The method of claim 3, wherein each of the plurality of main samples is obtained by recording a note played by a musical instrument, and each of the plurality of secondary samples is obtained by recording a note played by the same musical instrument of the corresponding main sample.

5. The method of claim 3, wherein each of the plurality of main samples comprises a recording of a note played by a musical instrument, and each of the plurality of secondary samples is obtained by recording of the same note of the corresponding main sample.

6. The method of claim 3, wherein each of the plurality of main samples is obtained by recording a note played by a musical instrument, and each of the plurality of secondary samples is obtained by time-truncating the note.

7. The method of claim 3, wherein each subset of IIR coefficients is derived from a truncated section of the corresponding main sample.

8. The method of claim 3, wherein the audio sample library comprises an M×N matrix having M main samples and N subsets of IIR coefficients, and wherein N=iM, wherein i is a positive integer equal to or larger than 1.

9. The method of claim 8, wherein the N main samples are of same dynamic layer.

10. The method of claim 8, wherein each of the IIR coefficients corresponds to a different dynamic layer from the N main samples.

11. The method of claim 1, wherein generating a set of infinite impulse response (IIR) coefficients comprises applying autoregressive model to a representation of each of the main samples.

12. The method of claim 11, wherein applying autoregressive model comprises applying Yule-Walker equations.

13. The method of claim 3, wherein each of the plurality of subsets of IIR coefficients is obtained by:
transforming selected secondary sample and selected main sample from time domain to frequency domain to generate secondary frequency spectrum magnitude and main frequency spectrum magnitude;
calculating a magnitude difference from the secondary frequency spectrum magnitude and main frequency spectrum magnitude;
extracting an envelope from the magnitude difference;
warping the envelope by scaling it onto a mel scale to obtained a warped envelope;
applying Yule-Walker equations to the warped envelop to obtain polynomial coefficients; and,
converting the polynomial coefficients from mel scale to linear scale to obtain IIR filter coefficients.

14. The method of claim 13, wherein extracting an envelope comprises dividing the magnitude difference into sub-octave bands and applying a window function to smooth each sub-octave band.

15. A method for deriving coefficients of IIR filter for sound recreation from a secondary sample corresponding to a main sample, comprising: transforming the secondary sample and the main sample from time domain to frequency domain to generate secondary frequency spectrum magnitude and main frequency spectrum magnitude; calculating a magnitude difference from the secondary frequency spectrum magnitude and main frequency spectrum magnitude; extracting an envelope from the magnitude difference; warping the envelope by scaling it onto a mel scale to obtained a warped envelope; applying Yule-Walker equations to the warped envelop to obtain polynomial coefficients; converting the polynomial coefficients from mel scale to linear scale to obtain IIR filter coefficients.

16. The method of claim 15, wherein converting the polynomial coefficients from mel scale to linear scale comprises rotating each pole and zero of the IIR filter.

17. The method of claim 15, further comprising smoothing the magnitude difference prior to extracting the envelope.

18. The method of claim 15, wherein applying Yule-Walker equations comprises using Yule-Walker coefficients to a plurality of filter orders.

19. A sample playback engine, comprising: an input receiving audio samples; an infinite impulse response (IIR) filter having coefficients derived from reference samples; a mixer controlling amount of IIR filter applied to the audio samples; and an output providing mixed samples resulting from application of the IIR filter to the audio samples.

20. The sample playback engine of claim 19, wherein the mixer is preprogrammed for a preset mixing amount.

21. The sample playback engine of claim 19, further comprising a user interface for controlling the mixing amount.

22. An audio sampler is provided, comprising:
a sample library having stored therein a plurality of main audio samples and a plurality of infinite impulse response (IIR) coefficients divided into subset, each subset corresponding to one of the main audio samples;
a sample playback engine comprising an input receiving the main audio samples and outputting a playback signal; and,
an IIR filter receiving the corresponding subset of IR coefficients and applying the IIR filter to the main audio samples or to the playback signal.
